(19) United States
(12) Patent Application Publication
(10) Pub. No.: US 2025/0253235 A1
(43) Pub. Date: Aug. 7, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yao-Jen TSAI, Hsinchu (TW); Chiu-Jung CHEN, Hsinchu (TW)

(73) Assignee: Taiwan Semiconductor Manufacturing Company, Ltd., Hsinchu (TW)

(21) Appl. No.: 18/432,333

(22) Filed: Feb. 5, 2024

(51) Int. Cl. H01L 23/522; H01L 21/768; H01L 23/528

(52) U.S. Cl. CPC H01L 23/5228; H01L 21/768; H01L 23/5222; H01L 23/5226; H01L 23/528; H10D 1/47; H10D 1/68

(57) ABSTRACT

A semiconductor device including a substrate, a first conductive feature, a second conductive feature, a first via structure, a second via structure and a metal-insulator-metal (MIM) structure is provided. The first conductive feature and the second conductive feature are disposed on the substrate, the first via structure is formed on the first conductive feature, the second via structure is formed on the second conductive feature, the MIM structure is disposed on the substrate, and the MIM structure includes a first metallization layer, a first insulating layer and a second metallization layer, the first insulating layer is located between the first and second metallization layers, the first metallization layer is electrically connected to the first and second via structures, and the second metallization layer is electrically connected to the first and second via structures.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor device according to an embodiment of the disclosure.

FIG. 2A is a schematic cross-sectional view of a semiconductor device according to an embodiment of the disclosure.

FIG. 2B is a schematic diagram of an equivalent circuit of the semiconductor device of FIG. 2A.

FIG. 3A is a schematic cross-sectional view of a semiconductor device according to an embodiment of the disclosure.

FIG. 3B is a schematic diagram of an equivalent circuit of the semiconductor device of FIG. 3A.

FIG. 4A is a schematic cross-sectional view of a semiconductor device according to an embodiment of the disclosure.

FIG. 4B is a schematic diagram of an equivalent circuit of the semiconductor device of FIG. 4A.

FIGS. 5A and 5B are respectively schematic plan views of a semiconductor device according to an embodiment of the present disclosure.

FIGS. 6A to 6D are respectively schematic cross-sectional views of a semiconductor device according to an embodiment of the present disclosure.

FIG. 7 is a schematic diagram of a method of manufacturing the semiconductor device of FIG. 6A.

FIG. 8 is a schematic diagram of a method of manufacturing the semiconductor device of FIG. 3A.

FIG. 9 is a schematic diagram of a method of manufacturing the semiconductor device of FIG. 2A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides various embodiments of on-wafer 3D MIM structures and methods of manufacturing the same. In some embodiments, 3D MIM structures are provided in a back-end-of-line (BEOL) of semiconductor devices, where individual devices in a substrate are interconnected with metallization structures and via structures in corresponding dielectric layers. This approach allows the construction of 3D MIM capacitors and/or resistors between multiple deep via structures in BEOL. Using the super-high-performance metal-insulator-metal (SHPMIM) process to produce vertically stacked resistors can save about 80% area or more of the substrate compared to horizontally placed resistors, in addition, the SHPMIM process can also produce vertically stacked resistors and horizontally placed resistors at the same time to increase design flexibility. In addition, in terms of making 3D capacitors and/or resistors, the SHPMIM process can form capacitors with larger capacitance values compared to horizontally counterparts with the same projected area, and can also make capacitors and/or resistors together, so that capacitors and resistors can share the same via structure. By forming such a 3D MIM structure in BEOL based on such manufacturing method, MIM capacitors and MIM resistors with large and tunable capacitance values or resistances can be achieved between active components and metallization layers or between two horizontal metallization layers. Finally, this manufacturing method does not increase the area burden of the BEOL, thereby improving the efficient use of substrate area for higher density ICs. Therefore, the above-mentioned problems can be advantageously avoided.

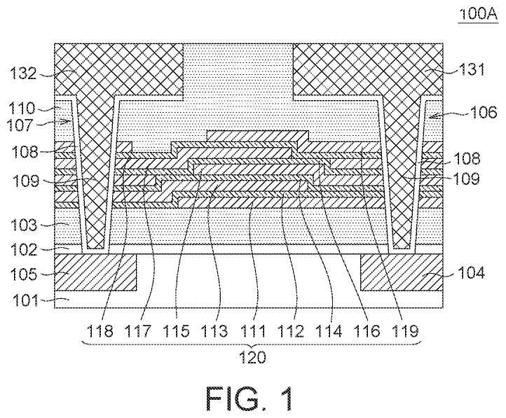

Referring to FIG. 1, a schematic cross-sectional view of a semiconductor device 100A according to an embodiment of the present disclosure is illustrated. Semiconductor device 100A includes a substrate 101, a first conductive feature 104, a second conductive feature 105, a first via structure 106, a second via structure 107, and a metal-insulator-metal (MIM) structure 120.

The semiconductor device 100A may be included in a microprocessor, memory cell, and/or other integrated circuit (IC). Also, FIG. 1 is simplified for a better understanding of the concepts of the present disclosure. Although the figures illustrate the semiconductor device 100A, it is understood the IC may comprise a number of other devices such as resistors, capacitors, inductors, fuses, etc., which are not shown in FIG. 1, for purposes of clarity of illustration.

Although the semiconductor device 100A in the illustrated embodiment of FIG. 1 includes only two conductive features (e.g., 104, 105), it is understood that the illustrated embodiment of FIG. 1 and the following figures are merely provided for illustration purposes. Thus, the semiconductor device 100A may include any desired number of conductive features while remaining within the scope of the present disclosure.

In some embodiments, the substrate 101 includes a silicon substrate. Alternatively, the substrate 101 may include other elementary semiconductor material such as, for example, germanium. The substrate 101 may also include a compound semiconductor such as silicon carbide, gallium arsenic, indium arsenide, and indium phosphide. The substrate 101 may include an alloy semiconductor such as silicon germanium, silicon germanium carbide, gallium arsenic phosphide, and gallium indium phosphide. In one embodiment, the substrate 101 includes an epitaxial layer. For example, the substrate 101 may have an epitaxial layer overlying a bulk semiconductor. Furthermore, the substrate 101 may include a semiconductor-on-insulator (SOT) structure. For example, the substrate 101 may include a buried oxide (BOX) layer formed by a process such as separation by implanted oxygen (SIMOX) or other suitable technique, such as wafer bonding and grinding.

In some embodiments, the substrate 101 also includes various p-type doped regions and/or n-type doped regions, implemented by a process such as ion implantation and/or diffusion. Those doped regions include n-well, p-well, lightly doped region (LDD), heavily doped source and drain (S/D), and various channel doping profiles configured to form various integrated circuit (IC) devices, such as a complimentary metal-oxide-semiconductor field-effect transistor (CMOSFET), imaging sensor, and/or light emitting diode (LED). The substrate 101 may further include other functional features such as a resistor or a capacitor formed in and on the substrate. The substrate 101 further includes lateral isolation features provided to separate various devices formed in the substrate 101, for example shallow trench isolation (STI). The various devices in the substrate 101 further include silicide disposed on S/D, gate and other device features for reduced contact resistance and enhance process compatibility when coupled between devices through local interconnections.

In an embodiment, the first and second conductive features 104 and 105 can be a source, drain or gate electrode. Alternatively, the conductive features 104 and 105 may be a silicide feature disposed on a source, drain or gate electrode typically from a sintering process introduced by at least one of the processes including thermal heating, laser irradiation or ion beam mixing. The silicide feature may be formed on polysilicon gate (typically known as “polycide gate”) or by on source/drain (typically known as “salicide”) by a self-aligned silicide technique. In another embodiment, the first and second conductive features 104 and 105 and may include an electrode of a capacitor or one end of a resistor.

The first and second via structures 104 and 105 may be a conductive plug. In some further embodiments, the semiconductor device 100A may include a barrier layer 108 surrounding sidewalls and bottom surface of the first and second via structures 104 and 105.

In some embodiments, the first and second via structure 104 and 105 may include a metal material 109 such as copper (Cu) or the like. In some other embodiments, the first and second via structures 104 and 105 may include other suitable metal materials (e.g., gold (Au), cobalt (Co), silver (Ag), etc.) and/or conductive materials (e.g., polysilicon) while remaining within the scope of the present disclosure.

In some embodiments, the barrier layer 108 includes a conductive material such as a metal, a metal alloy, or a metal nitride, for example, tantalum nitride (TaN), tantalum (Ta), titanium nitride (TiN), titanium (Ti), cobalt tungsten (CoW), tungsten nitride (WN), or the like. The barrier layer 108 may effectively prevent metal atoms from diffusing into the ILD layers 103 and 110 during a metal deposition process to form the first and second via structures 104 and 105, which will be discussed below.

The first and second via structures 104 and 105 may be formed by at least some of the following process steps: using chemical vapor deposition (CVD), physical vapor deposition (PVD), spin-on coating, and/or other suitable techniques to deposit a etch stop layer 102, a first interlayer dielectric (ILD) layer 103, multi-layers of the MIM structure 120, and a second ILD layer 110 over the substrate 101 with the first and second conductive features 104 and 105; performing one or more patterning processes (e.g., a lithography process, a dry/wet etching process, a soft/hard baking process, and a cleaning process, etc.) to form a via hole through the etch stop layer 102, the first ILD layer 103, the MIM structure 120, and the second ILD layer 110; using CVD, PVD, and/or other suitable techniques to deposit the barrier layer 108 along a bottom surface and sidewalls of the via hole to surround the via hole; using CVD, PVD, E-gun, and/or other suitable techniques to fill the via hole with a metal material 109, and polishing out excessive metal material 109 by a planarization process (e.g., chemical-mechanical polishing) to form the first and second via structures 104 and 105 with the barrier layer 108. In some embodiments, the etch stop layer 102 may be formed from a conductive material such as titanium nitride (TiN) or the like.

Referring to FIG. 1, the first conductive feature 104 and the second conductive feature 105 are disposed on the substrate 101. In some embodiments, the etch stop layer 102 and the ILD layer 103 cover the first conductive feature 104 and the second conductive feature 105. The MIM structure 120 is disposed on the ILD layer 103, and the MIM structure 120 includes multiple metallization layers and multiple insulating layers alternately stacked, the number of layers is greater than three, but is not limited thereto. In some embodiments, the MIM structure 120 includes a first metallization layer 111, a first insulating layer 112, a second metallization layer 113, a second insulating layer 114, a third metallization layer 115, a third insulating layer 116, a fourth metallization layer 117, a fourth insulating layer 118 and a fifth metallization layer 119 in order from bottom to top. That is to say, any two adjacent metallization layers among the first metallization layer 111, the second metallization layer 113, the third metallization layer 115, the fourth metallization layer 117 and the fifth metallization layer 119 are insulated to each other and stacked to form a MIM capacitor.

In some embodiments, the MIM capacitor comprises a material with a high dielectric constant, e.g., a high-k dielectric material, for example Al₂O₃, HfO₂, SiO₂, La₂O₃, ZrO₃, Ba—Sr—Ti—O, Si₃N₄ and laminate of a mixture thereof. The MIM capacitor can be formed by various processes including deposition a dielectric layer using PVD, CVD and the like, photolithography and a dry/wet etching process. The thickness of this MIM capacitor is controlled by the desired capacitance value, which is a function of the area of the metallization layers and the dielectric constant of the dielectric material of the MIM capacitor. In some embodiments, the thickness of the MIM capacitor that contains five metallization layers can be in a range of a few hundreds of nanometers to a few thousands of nanometers, e.g., 200-1000 nanometers.

In some embodiments, when MIM capacitors are used in RF circuits, the dielectric loss may be extremely small and the series resistance of the wiring may be minimized for high frequency applications. This indicates that it is desirable to use short interconnect wires with low specific resistance. As MIM-capacitors are constructed using the back-end metallization layers, the process temperature for the MIM capacitors, particularly the deposition temperature of the MIM capacitor, may be low enough to be compatible with the metallization stack and the low-k dielectric layers.

Referring to FIG. 1, a first via structure 106 is formed on the first conductive feature 104. The first via structure 106 penetrates the MIM structure 120, the ILD layers 103, 110 and the etch stop layer 102, and the first via structure 106 is electrically connected to odd-numbered metallization layers (for example, 111, 115, 119), For example, the 1st, 3rd, 5th, . . . , 2n−1 layers in the metallization layers, n is a positive integer greater than 0. In addition, the second via structure 107 is formed on the second conductive feature 105 and penetrates the MIM structure 120, the ILD layers 103, 110 and the etch stop layer 102, and the second via structure 107 is electrically connected to even-numbered metallization layers (for example, 113, 117), For example, the 2nd, 4th, 6th, . . . , 2nth layers in the metallization layers, n is a positive integer greater than 0.

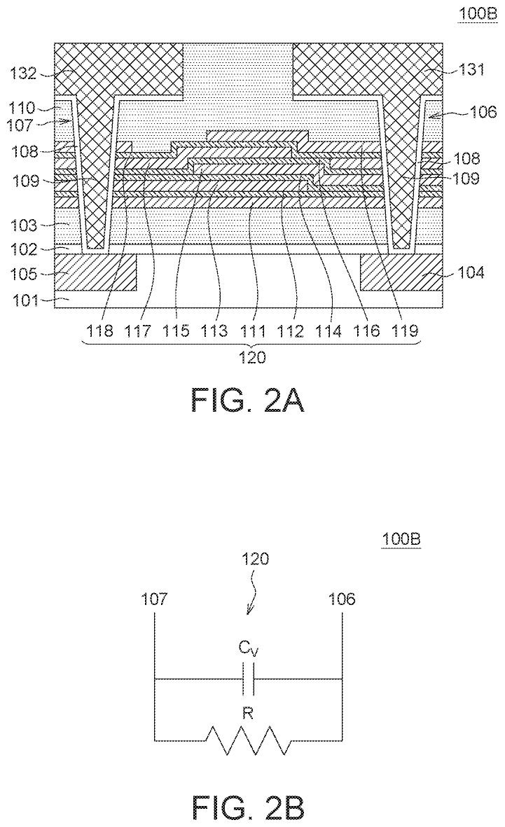

Referring to FIG. 2A, a schematic cross-sectional view of a semiconductor device 100B according to an embodiment of the present disclosure is illustrated. The semiconductor device 100B includes a substrate 101, a first conductive feature 104, a second conductive feature 105, a first via structure 106, a second via structure 107, and a metal-insulator-metal (MIM) structure. 120. In some embodiments, the MIM structure 120 includes a first metallization layer 111, a first insulating layer 112, a second metallization layer 113, a second insulating layer 114, a third metallization layer 115, a third insulating layers 116, a fourth metallization layer 117, a fourth insulating layer 118 and a fifth metallization layer 119 in order from bottom to top, but the number of layers is not limited. This embodiment is substantially the same as the above-mentioned embodiment, and the same/similar reference numbers represent the same/similar components. The difference lies in that the first metallization layer 111 is electrically connected to the first via structure 106 and the second via structure 107 to form a resistor between the first via structure 106 and the second via structure 107. Therefore, the first via structure 106 is electrically connected to odd-numbered of metallization layers (such as 111, 115, 119). In addition to being connected to the first metallization layer 111, the second via structure 107 is also electrically connected to even-numbered metallization layers (such as 113, 117).

Referring to FIG. 2B, a schematic diagram of the equivalent circuit of the semiconductor device 100B of FIG. 2A is illustrated. In one embodiment, a resistor R and a MIM capacitor Cv are connected in parallel and located between the first via structure 106 and the second via structure 107 to form an RC circuit. The resistor R may be formed from at least one of the plurality of metallization layers, and the MIM capacitor Cv may be formed from any two adjacent metallization layers of the plurality of metallization layers. Since the resistor R and the MIM capacitor Cv are stacked vertically, the area burden can be saved compared to a horizontally placed resistor, thereby improving the effective use of the substrate area of a higher density IC.

However, the present disclosure is not limited to forming only a single resistor R. In other embodiments, the present disclosure can form a vertically stacked resistor, that is, a structure in which multiple resistors R are stacked vertically. In some embodiments, the thickness of the resistor R may be in the range of 200 nm to 1000 nm, and the resistance value of the resistor R may be in the range of few ohms to few tens of ohms, such as 1-20 ohms. Vertically stacked resistors can be used in radio frequency (RF) circuits or mixed circuits, such as analog-to-digital converter (ADC), VOC, filters, Inductor-Capacitor (LC) tanks, and de-coupling circuits, but the disclosure is not limited thereto.

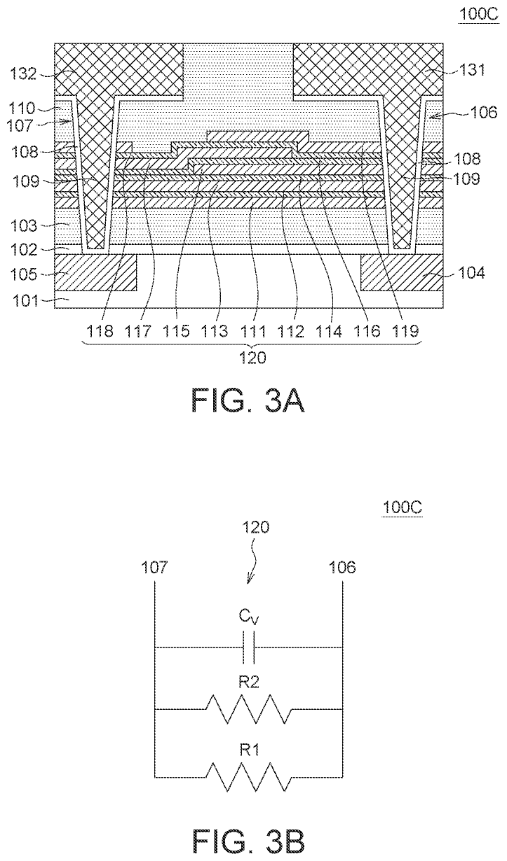

Referring to FIG. 3A, a schematic cross-sectional view of a semiconductor device 100C according to an embodiment of the present disclosure is illustrated. The semiconductor device 100C includes a substrate 101, a first conductive feature 104, a second conductive feature 105, a first via structure 106, a second via structure 107, and a metal-insulator-metal (MIM) structure 120. In some embodiments, the MIM structure 120 includes a first metallization layer 111, a first insulating layer 112, a second metallization layer 113, a second insulating layer 114, a third metallization layer 115, a third insulating layers 116, a fourth metallization layer 117, a fourth insulating layer 118 and a fifth metallization layer 119 in order from bottom to top, but the number of layers is not limited. The difference between this embodiment and the above-mentioned embodiment is that the first metallization layer 111 and the second metallization layer 113 are electrically connected to the first via structure 106 and the second via structure 107 respectively to form two resistors between the first via structure 106 and the second via structure 107. The two resistors are connected in parallel and stacked vertically, while the remaining three or more metallization layers are electrically isolated from each other and staggered to form a MIM capacitor.

Referring to FIG. 3B, a schematic diagram of the equivalent circuit of the semiconductor device 100C of FIG. 3A is illustrated. In one embodiment, two resistors R1 and R2 and a MIM capacitor C are connected in parallel and located between the first via structure 106 and the second via structure 107 to form an RC circuit. The resistors R1 and R2 may be formed by at least two layers among the plurality of metallization layers, and the MIM capacitor Cv may be formed by any two adjacent metallization layers among the plurality of metallization layers. Since the two resistors R1, R2 and the MIM capacitor Cv are vertically stacked, the area burden compared to horizontally placed resistors can be saved, thereby improving the effective use of the substrate area of higher density ICs.

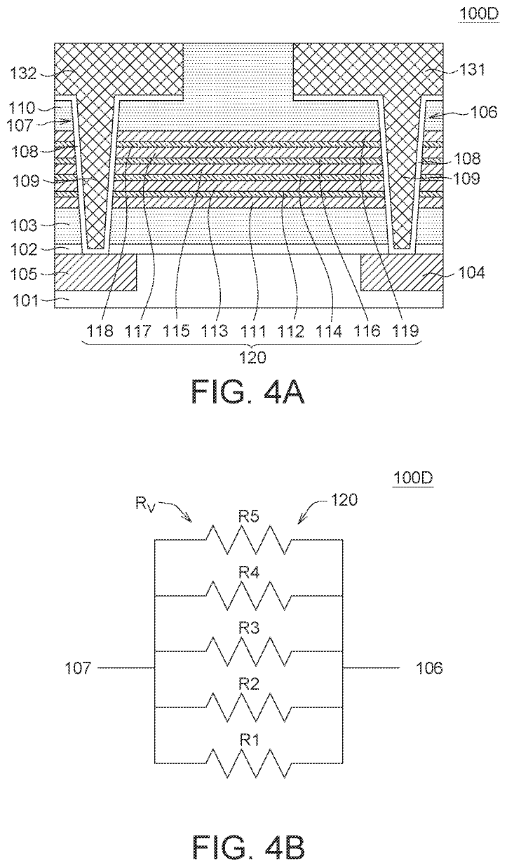

Referring to FIG. 4A, a schematic cross-sectional view of a semiconductor device 100D according to an embodiment of the present disclosure is illustrated. The semiconductor device 100D includes a substrate 101, a first conductive feature 104, a second conductive feature 105, a first via structure 106, a second via structure 107, and a metal-insulator-metal (MIM) structure. 120. In some embodiments, the MIM structure 120 includes a first metallization layer 111, a first insulating layer 112, a second metallization layer 113, a second insulating layer 114, a third metallization layer 115, a third insulating layer 116, a fourth metallization layer 117, a fourth insulating layer 118 and a fifth metallization layer 119 in order from bottom to top, but the number of layers is not limited. The difference between this embodiment and the above-mentioned embodiments is that: the first metallization layer 111, the second metallization layer 113, the third metallization layer 115, the fourth metallization layer 117, and the fifth metallization layer 119 are electrically connected to the first via structure 106 and the second via structure 107 respectively to form five resistors between the first via structure 106 and the second via structure 107. The five resistors are connected in parallel and vertically stacked to form a vertically stacked resistor R_{V} (as shown in FIG. 4B).

Referring to FIG. 4B, a schematic diagram of the equivalent circuit of the semiconductor device 100D of FIG. 4A is illustrated. In one embodiment, a plurality of resistors R1 to R5 are connected in parallel and are located between the first via structure 106 and the second via structure 107. The number of resistors R1 to R5 may be one or more. Since the resistors R1 to R5 are vertically stacked, area burden compared to horizontally placed resistors can be saved, thereby improving the effective utilization of the substrate area of higher density ICs.

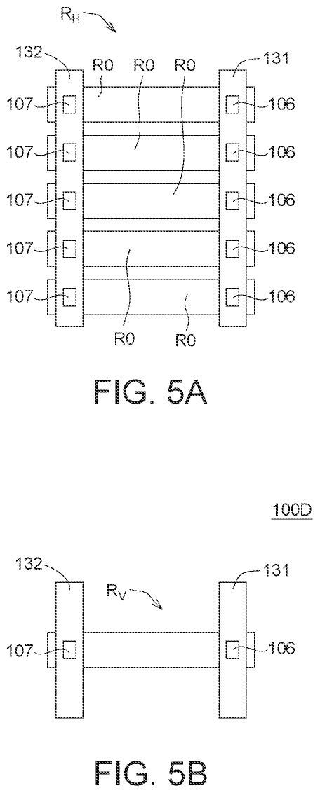

Referring to FIGS. 5A and 5B, schematic plan views of a semiconductor device according to an embodiment of the present disclosure are respectively illustrated. In FIG. 5A, the semiconductor device may include a horizontally placed resistor R_{H}, which includes a plurality of resistors R0 placed on a plane, each resistor R0 does not overlap and is located between the corresponding first via structure 106 and the second via structures 107. The first via structures 106 are electrically connected to a first conductive line 131, and the second via structures 107 are electrically connected to a second conductive line 132 to form a horizontally placed resistor R_{H} between the first conductive line 131 and the second conductive line 132. In FIG. 5B, the semiconductor device 100D may include a vertically stacked resistor R_{V}, which includes a plurality of vertically stacked resistors. As shown in FIG. 4B, each resistor shares the same first via structure 106 and the second via structure 107. The first via structure 106 is electrically connected to a first conductive line 131, and the second via structure 107 is electrically connected to a second conductive line 132 to form a vertically stacked resistor R_{V} between the first conductive line 131 and the second conductive line 132. It can be seen from the plan view that the vertically stacked resistor R_{V} can save 80% area of the substrate 101 compared to the horizontally placed resistor R_{H}. In addition, the semiconductor device and the manufacturing method thereof of the present disclosure can also produce vertically stacked resistors R_{V} and horizontally placed resistors R_{H} at the same time to increase design flexibility.

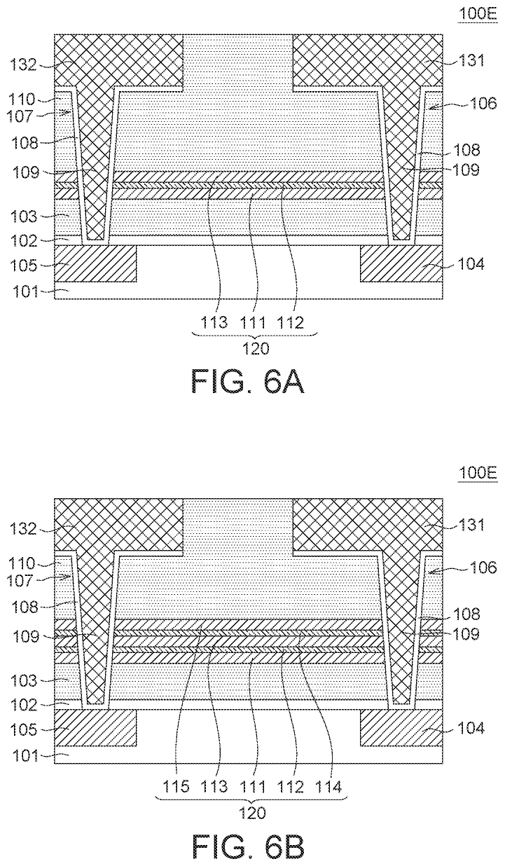

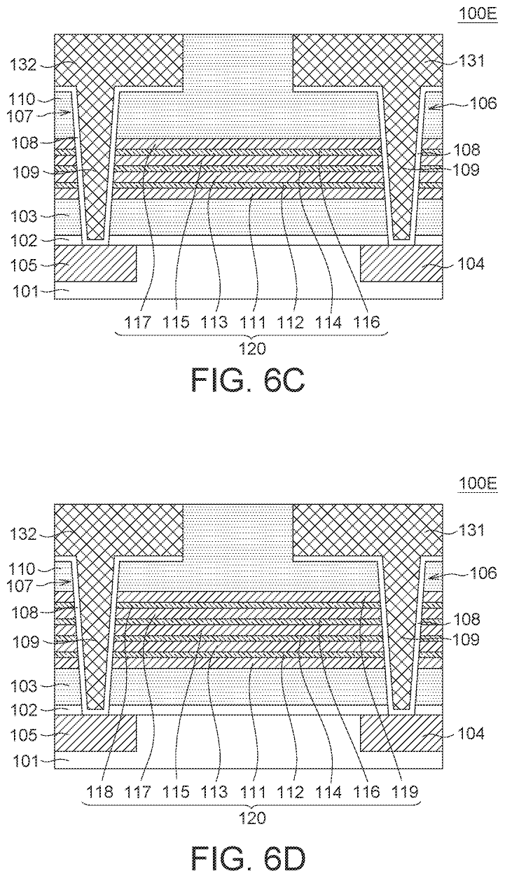

Referring to FIGS. 6A to 6D, schematic cross-sectional views of a semiconductor device 100E according to an embodiment of the present disclosure are respectively illustrated. Semiconductor device 100E includes a substrate 101, a first conductive feature 104, a second conductive feature 105, a first via structure 106, a second via structure 107, and a metal-insulator-metal (MIM) structure. 120. In FIG. 6A, the MIM structure 120 includes a first metallization layer 111, a first insulating layer 112 and a second metallization layer 113. The first insulating layer 112 is located between the first metallization layer 111 and the second metallization layer 113. The first metallization layer 111 is electrically connected to the first via structure 106 and the second via structure 107, and the second metallization layer 113 is electrically connected to the first via structure 106 and the second via structure 107. In FIG. 6B, the MIM structure 120 includes a first metallization layer 111, a first insulating layer 112, a second metallization layer 113, a second insulating layer 114 and a third metallization layer 115. The insulating layer 112 is located between the first metallization layer 111 and the second metallization layer 113, and the second insulating layer 114 is located between the second metallization layer 113 and the third metallization layer 115. The first metallization layer 111, the second metallization layer 113 and the third metallization layer 115 are all electrically connected to the first via structure 106 and the second via structure 107. The MIM structures 120 of FIGS. 6C and 6D are generally similar to the MIM structures 120 of FIGS. 6A and 6B, and the only difference lies in the number of stacked layers.

The methods of manufacturing semiconductor devices 100A to 100E in different embodiments of the present disclosure are described as follows. The methods of manufacturing semiconductor devices 100A to 100E in each embodiment include the following steps. First, a MIM structure 120 is formed on the substrate 101. The MIM structure 120 includes at least one of the MIM structures 120 described in FIG. 1, FIG. 2A, FIG. 3A, FIG. 4A, and FIGS. 6A to 6D. Next, a first via structure 106 is formed on a first conductive feature 104. The first via structure 106 penetrates the MIM structure 120. The first via structure 106 is electrically connected to at least one of a plurality of metallization layers in the MIM structure 120. Next, a second via structure 107 is formed on a second conductive feature 105. The second via structure 107 penetrates the MIM structure 120. The second via structure 107 is electrically connected to at least one of a plurality of metallization layers in the MIM structure 120 so as to form at least one resistor, at least one capacitor, or at least one resistor and at least one capacitor between the first via structure 106 and the second via structure 107.

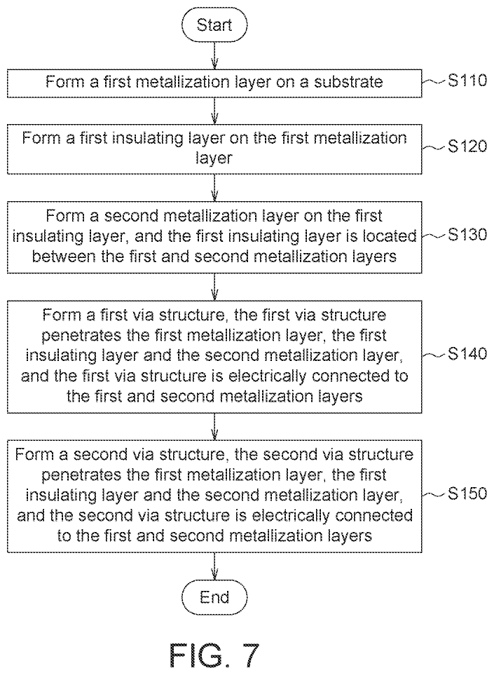

For more details, referring to FIG. 6A and FIG. 7, FIG. 7 is a schematic diagram of a method of manufacturing the semiconductor device 100E of FIG. 6A. In step S110, a first metallization layer 111 is formed on a substrate 101. In step S120, a first insulating layer 112 is formed on the first metallization layer 111. In step S130, a second metallization layer 113 is formed on the first insulating layer 112. The first insulating layer 112 is located between the first metallization layer 111 and the second metallization layer 113 to form a MIM structure 120. In step S140, a first via structure 106 is formed on a first conductive feature 104, and the first via structure 106 penetrates the first metallization layer 111, the first insulating layer 112 and the second metallization layer 113. The first via structure 106 is electrically connected to the first metallization layer 111 and the second metallization layer 113. In step S150, a second via structure 107 is formed on a second conductive feature 105, and the second via structure 107 penetrates the first metallization layer 111, the first insulating layer 112 and the second metallization layer 113, The second via structure 107 is electrically connected to the first metallization layer 111 and the second metallization layer 113. It can be seen from the above process method that the first metallization layer 111 forms a first resistor R1, and the second metallization layer 113 forms a second resistor R2. The first resistor R1 and the second resistor R2 are connected in parallel and stacked vertically to improve the effective utilization of the area of the substrate 101. To form more capacitors, the method includes repeating the above MIM process at least once.

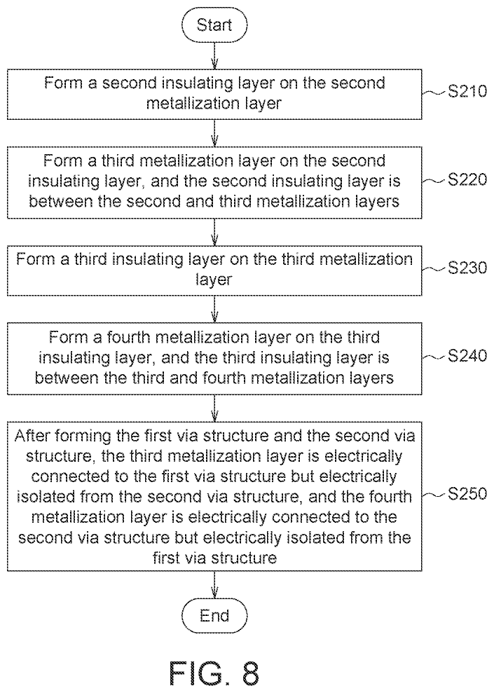

Referring to FIG. 3A and FIG. 8. FIG. 8 is a schematic diagram of a method of manufacturing the semiconductor device 100C of FIG. 3A. The steps of forming the MIM structure 200 in FIG. 7 further include: in step S210, a second insulating layer 114 is formed on the second metallization layer 113. In step S220, a third metallization layer 115 is formed on the second insulating layer 114. In step S230, a third insulating layer 116 is formed on the third metallization layer 115. In step S240, a fourth metallization layer 117 is formed on the third insulating layer 116, and the third insulating layer 116 is located between the third metallization layer 115 and the fourth metallization layer 117. In step S250, after forming the first via structure 106 and the second via structure 107 in FIG. 7, the third metallization layer 115 is electrically connected to the first via structure 106 but is electrically isolated from the second via structure 107. The fourth metallization layer 117 is electrically connected to the second via structure 107 but is electrically isolated from the first via structure 106. Therefore, the third metallization layer 115 and the fourth metallization layer 117 form a capacitor Cv, and the first resistor R1, the second resistor R2 and the capacitor Cv are connected in parallel and vertically stacked.

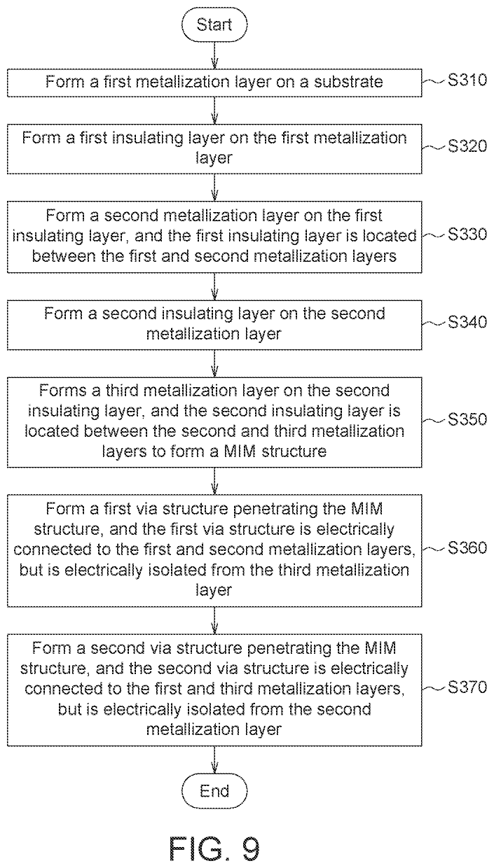

Referring to FIG. 2A and FIG. 9. FIG. 9 is a schematic diagram of a method of manufacturing the semiconductor device 100B of FIG. 2A. In step S310, a first metallization layer 111 is formed on a substrate 101. In step S320, a first insulating layer 112 is formed on the first metallization layer 111. In step S330, a second metallization layer 113 is formed on the first insulating layer 112, and the first insulating layer 112 is located between the first metallization layer 111 and the second metallization layer 113. In step S340, a second insulating layer 114 is formed on the second metallization layer 113. In step S350, a third metallization layer 115 is formed on the second insulating layer 114, and the second insulating layer 114 is located between the second metallization layer 113 and the third metallization layer 115, and so on. A MIM structure 120 is formed. In step S360, a first via structure 106 is formed on a first conductive feature 104. The first via structure 106 penetrates the MIM structure 120. The first via structure 106 is electrically connected with the first metallization layer 111 and the second metallization layer 113, but is electrically isolated from the third metallization layer 115. In step S370, a second via structure 107 is formed on a second conductive feature 105. The second via structure 107 penetrates the MIM structure 120. The second via structure 107 is electrically connected with the first metallization layer 111 and the third metallization layer 115, but is electrically isolated from the second metallization layer 113. It can be seen from the above process method that the first metallization layer 111 forms a resistor R, and the second metallization layer 113 and the third metallization layer 115 form a capacitor Cv. To form multiple resistors and/or capacitors, the above-mentioned MIM process only needs to be repeated at least once (refer to step S230 and step S240 in FIG. 7), so as to improve the effective utilization of the area of the substrate 101.

The present disclosure is related to a semiconductor device and a manufacturing method thereof, the SHPMIM process is used to produce vertically stacked resistors to save 80% area of the substrate compared to horizontally placed resistors, in addition, the SHPMIM process can also produce vertically stacked resistors and horizontally placed resistors at the same time to increase design flexibility. In addition, in terms of making 3D capacitors and/or resistors, the SHPMIM process can form capacitors with larger capacitance values compared to horizontally counterparts with the same projected area, and can also make capacitors and resistors together, so that capacitors and/or resistors can share the same via structure.

According to an embodiment of the present disclosure, a semiconductor device including a substrate, a first conductive feature, a second conductive feature, a first via structure, a second via structure and a metal-insulator-metal (MIM) structure is provided. The first conductive feature and the second conductive feature are disposed on the substrate, the first via structure is formed on the first conductive feature, the second via structure is formed on the second conductive feature, the MIM structure is disposed on the substrate, and the MIM structure includes a first metallization layer, a first insulating layer and a second metallization layer, the first insulating layer is located between the first and second metallization layers, the first metallization layer is electrically connected to the first and second via structures, and the second metallization layer is electrically connected to the first and second via structures.

According to an embodiment of the present disclosure, a semiconductor device including a substrate, a first conductive feature, a second conductive feature, a first via structure, a second via structure and a metal-insulator-metal (MIM) structure is provided. The first conductive feature and the second conductive feature are disposed on the substrate, the first via structure is formed on the first conductive feature, the second via structure is formed on the second conductive feature, the MIM structure is disposed on the substrate, and the MIM structure includes a first metallization layer, a first insulating layer, a second metallization layer, a second insulating layer and a third metallization layer, the first insulating layer is located between the first and second metallization layers, and the second insulating layer is located between the second and third metallization layers. The first metallization layer is electrically connected to the first and second via structures, the second metallization layer is electrically connected to the second via structure but is electrically isolated from the first via structure, and the third metallization layer is electrically connected to the first via structure but is electrically isolated from the second via structure.

According to an embodiment of the present disclosure, a method of manufacturing a semiconductor device is provided, including the following steps. a metal-insulator-metal (MIM) structure is formed on a substrate, the MIN structure includes a plurality of metallization layers stacked vertically to each other. A first via structure is formed on a first conductive feature, the first via structure penetrating the MIM structure, the first via structure being electrically connected to at least one of the metallization layers. A second via structure is formed on a second conductive feature, the second via structure penetrates the MIM structure, and the second via structure is electrically connected to at least one of the metallization layers. At least one resistor, at least one capacitor, or at least one resistor and at least one capacitor are electrically connected between the first and second via structures through the MIM structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first conductive feature disposed on the substrate;
a second conductive feature disposed on the substrate;
a first via structure formed on the first conductive feature;
a second via structure formed on the second conductive feature; and
a metal-insulator-metal (MIM) structure disposed on the substrate, wherein the MIM structure comprises a first metallization layer, a first insulating layer and a second metallization layer, the first insulating layer is located between the first and second metallization layers, wherein the first metallization layer is electrically connected to the first and second via structures, and the second metallization layer is electrically connected to the first and second via structures.

2. The semiconductor device according to claim 1, wherein the first metallization layer forms a first resistor, the second metallization layer forms a second resistor, and the first resistor and the second resistor are connected in parallel and stacked vertically to each other.

3. The semiconductor device according to claim 1, wherein the MIM structure comprises a third metallization layer, a second insulating layer and a fourth metallization layer, the second insulating layer is located between the third and fourth metallization layers, wherein the third metallization layer is electrically connected to the first via structure but is electrically isolated from the second via structure, and the fourth metallization layer is electrically connected to the second via structure but is electrically isolated from the first via structure.

4. The semiconductor device according to claim 3, wherein the first metallization layer forms a first resistor, the second metallization layer forms a second resistor, and the third and fourth metallization layers form a capacitor, wherein the first resistor, the second resistor and the capacitor are connected in parallel and stacked vertically to each other.

5. The semiconductor device according to claim 4, wherein each of the first resistor and the second resistor has a resistance of 1-20 ohms.

6. The semiconductor device according to claim 1, wherein the MIM structure has a thickness of 200-1000 nanometers.

7. A semiconductor device, comprising:
a substrate;
a first conductive feature disposed on the substrate;
a second conductive feature disposed on the substrate;
a first via structure formed on the first conductive feature;
a second via structure formed on the second conductive feature; and
a metal-insulator-metal (MIM) structure disposed on the substrate, wherein the MIM structure comprises a first metallization layer, a first insulating layer, a second metallization layer, a second insulating layer and a third metallization layer, the first insulating layer is located between the first and second metallization layers, the second insulating layer is located between the second and third metallization layers,
wherein the first metallization layer is electrically connected to the first and second via structures, the second metallization layer is electrically connected to the second via structure but is electrically isolated from the first via structure, and the third metallization layer is electrically connected to the first via structure but is electrically isolated from the second via structure.

8. The semiconductor device according to claim 7, wherein the first metallization layer forms a resistor, the second metallization layer and the third metallization layer form a capacitor, the resistor is connected in parallel with the capacitor and vertically stacked to each other.

9. The semiconductor device according to claim 7, wherein the MIM structure further comprises a third insulating layer and a fourth metallization layer, the third insulating layer is located on the third metallization layer and the fourth metallization layer. wherein the fourth metallization layer is electrically connected to the second via structure but electrically isolated from the first via structure.

10. The semiconductor device according to claim 9, wherein the first metallization layer forms a resistor, the second metallization layer and the third metallization layer form a first capacitor, and the third metallization layer and the fourth metallization layer forms a second capacitor, and the resistor, the first capacitor and the second capacitor are connected in parallel and vertically stacked to each other.

11. A method of manufacturing a semiconductor device, including:
forming a metal-insulator-metal (MIM) structure on a substrate, the MIN structure comprises a plurality of metallization layers stacked vertically to each other;
forming a first via structure on a first conductive feature, the first via structure penetrating the MIM structure, the first via structure being electrically connected to at least one of the metallization layers;
forming a second via structure on a second conductive feature, the second via structure penetrating the MIM structure, the second via structure being electrically connected to at least one of the metallization layers; and
at least one resistor, at least one capacitor, or at least one resistor and at least one capacitor are electrically connected between the first and second via structures through the MIM structure.

12. The method of manufacturing a semiconductor device according to claim 11, wherein forming the MIM structure comprises:
forming a first metallization layer on the substrate;
forming a first insulating layer on the first metallization layer; and
forming a second metallization layer on the first insulating layer, the first insulating layer being located between the first and second metallization layers,
wherein the first metallization layer is electrically connected to the first and second via structures, and the second metallization layer is electrically connected to the first and second via structures.

13. The method of manufacturing a semiconductor device according to claim 12, wherein the first metallization layer forms a first resistor, the second metallization layer forms a second resistor, and the first and second resistors are connected in parallel and stacked vertically to each other.

14. The method of manufacturing a semiconductor device according to claim 12, wherein forming the MIM structure further comprises:
forming a second insulating layer on the second metallization layer;
forming a third metallization layer on the second insulating layer, the second insulating layer being located between the second and third metallization layers;
forming a third insulating layer on the third metallization layer; and
forming a fourth metallization layer on the third insulating layer, the third insulating layer being located between the third and fourth metallization layers,
after forming the first and second via structures, the third metallization layer is electrically connected to the first via structure but electrically isolated from the second via structure, and the fourth metallization layer is electrically connected to the first via structure but electrically isolated from the first via structure.

15. The method of manufacturing a semiconductor device according to claim 14, wherein the first metallization layer forms a first resistor, the second metallization layer forms a second resistor, and the third and fourth metallization layers form a capacitor, and the first resistor, the second resistor and the capacitor are connected in parallel and stacked vertically to each other.

16. The method of manufacturing a semiconductor device according to claim 11, wherein forming the MIM structure comprises:
forming a first metallization layer on the substrate;
forming a first insulating layer on the first metallization layer;
forming a second metallization layer on the first insulating layer, the first insulating layer being located between the first and second metallization layers;
forming a second insulating layer on the second metallization layer; and
forming a third metallization layer on the second insulating layer, the second insulating layer being located between the second and third metallization layers,
the first metallization layer is electrically connected to the first and second via structures, the second metallization layer is electrically connected to the second via structure but is electrically isolated from the first via structure, and the third metallization layer is electrically connected to the first via structure but is electrically isolated from the second via structure.

17. The method of manufacturing a semiconductor device according to claim 16, wherein the first metallization layer forms a resistor, the second and third metallization layers form a capacitor, and the resistor and the capacitor connected in parallel and stacked vertically to each other.

18. The method of manufacturing a semiconductor device according to claim 16, wherein forming the MIM structure further comprises:
forming a third insulating layer on the third metallization layer; and
forming a fourth metallization layer on the third insulating layer, the third insulating layer is located between the third and the fourth metallization layers, wherein the fourth metallization layer and the second via structure is electrically connected but electrically isolated from the first via structure.

19. The method of manufacturing a semiconductor device according to claim 18, wherein the first metallization layer forms a resistor, the second and third metallization layers form a first capacitor, and the third and fourth metallization layers form a second capacitor, and the resistor, the first capacitor and the second capacitor are connected in parallel and stacked vertically to each other.

20. The method of manufacturing a semiconductor device according to claim 11, wherein the MIM structure has a thickness of 200-1000 nanometers.
